(19) United States
(12) Patent Application Publication
(10) Pub. No.: US 2017/0041086 A1
(43) Pub. Date: Feb. 9, 2017

(54) DATA TRANSMISSION APPARATUS FOR CHANGING CLOCK SIGNAL AT RUNTIME AND DATA INTERFACE SYSTEM INCLUDING THE SAME

(71) Applicant: Samsung Electronics Co., Ltd., Suwon-si (KR)

(72) Inventors: Seung Beom PARK, Hwaseong-si (KR); Hong Sik PARK, Hwaseong-si (KR); Jong Hyup LEE, Seoul (KR)

(73) Assignee: Samsung Electronics Co., Ltd., Suwon-si (KR)

(21) Appl. No.: 15/223,524

(22) Filed: Jul. 29, 2016

(30) Foreign Application Priority Data
Aug. 3, 2015 (KR) 10-2015-0109741

(51) Int. Cl. H04B 15/02; H04B 17/00; H03L 7/07

(52) U.S. Cl. CPC H04B 15/02; H03L 7/07; H04B 17/0085

(57) ABSTRACT

In an example embodiment, a data transmission apparatus includes a transmission link module configured to generate a reference clock signal and a transmission D-PHY module. The transmission D-PHY module includes a first phase locked loop configured to receive the reference clock signal, and generate a first clock signal. The transmission D-PHY module further includes a second phase locked loop configured to receive the reference clock signal, and generate a second clock signal having a different frequency than the first clock signal. The transmission D-PHY module further includes a multiplexer configured to select and output one of the first and second clock signals as a clock signal according to a selection signal. The transmission D-PHY module further includes a data transmitter configured to convert parallel data into serial data in response to the clock signal for transmission to a receiver.

### CROSS-REFERENCE TO RELATED APPLICATIONS

This application claims priority under 35 U.S.C. §119(a) to Korean Patent Application No. 10-2015-0109741 filed on Aug. 3, 2015, the disclosure of which is hereby incorporated by reference in its entirety.

### BACKGROUND

An interface for display devices or image sensors typically uses a method of transmitting data in series. Such serial interface may include low voltage differential signaling (LVDS) interface and mobile industry processor interface (MIPI). MIPI display serial interface (DSI) is a recent display standard for portable electronic devices. MIPI supports two display standards, i.e., a video mode and a command mode.

In either the video mode or the command mode, frame data (or command) is transmitted from a host to a display driver integrated circuit (IC) in real time. At this time, a clock frequency and a communication frequency perturb each other in MIPI DSI, thereby causing electromagnetic interference (EMI). In order to avoid EMI, shielding and/or an EMI filter frequency is used.

### SUMMARY

In one or more example embodiments, a data transmission apparatus includes a transmission link module configured to generate a reference clock signal and a transmission D-PHY module. The transmission D-PHY module includes a first phase locked loop configured to receive the reference clock signal, and generate a first clock signal. The transmission D-PHY module further includes a second phase locked loop configured to receive the reference clock signal, and generate a second clock signal having a different frequency than the first clock signal. The transmission D-PHY module further includes a multiplexer configured to select and output one of the first and second clock signals as a clock signal according to a selection signal. The transmission D-PHY module further includes a data transmitter configured to convert parallel data into serial data in response to the clock signal for transmission to a receiver.

In yet another example embodiment, the transmission link module includes a multiplexer selection logic configured to output the selection signal to the multiplexer in response to a clock change request.

In yet another example embodiment, the first phase locked loop is enabled in response to a first enable signal and the second phase locked loop is enabled in response to a second enable signal, the first enable signal and the second enable signal being generated by the transmission link module.

In yet another example embodiment, multiplexer selection logic is configured to enable one of the first phase locked loop and the second phase locked loop, that is not enabled when the multiplexer selection logic receives the clock change request.

In yet another example embodiment, if both of the first phase locked loop and the second phase locked loop are enabled, the multiplexer selection logic is configured to output the selection signal to the multiplexer after a current frame data transmission is completed.

In yet another example embodiment, the multiplexer selection logic is configured to change and output the selection signal to the multiplexer at a time of a next frame, and disable a phase locked loop which is not selected by the multiplexer among the first and second phase locked loops.

In yet another example embodiment, the time is determined to be in one of a vertical sync active period, a vertical back porch, and a vertical front porch, and the multiplexer is configured to select and output a clock signal that does not interfere with a communication frequency of the data transmission apparatus.

In yet another example embodiment, the transmission D-PHY module further includes a multiplexer selection logic configured to output the selection signal to the multiplexer in response to a clock change request.

In yet another example embodiment, the data transmission apparatus further includes a multiplexer selection logic located between the transmission link module and the transmission D-PHY module, the multiplexer selection logic configured to output the selection signal to the multiplexer in response to a clock change request.

In one or more example embodiments, a data interface system includes a receiver, a data communication link, a clock communication link and a transmitting apparatus. The transmitting apparatus includes a transmission link module and a transmission D-PHY module. The transmission D-PHY module includes a first phase locked loop configured to receive a reference clock signal, and generate a first clock signal. The transmission D-PHY module further includes a second phase locked loop configured to receive the reference clock signal, and generate a second clock signal having a different frequency than the first clock signal. The transmission D-PHY module further includes a multiplexer configured to select and output either of the first and second clock signals as a clock signal according to a selection signal. The transmission D-PHY module further includes a data transmitter configured to convert parallel data into serial data in response to the clock signal for transmission to the receiver.

In yet another example embodiment, the transmission link module includes a multiplexer selection logic configured to output the selection signal to the multiplexer in response to a clock change request.

In yet another example embodiment, the first phase locked loop is enabled in response to a first enable signal and the second phase locked loop is enabled in response to a second enable signal.

In yet another example embodiment, the multiplexer selection logic is configured to enable one of the first phase locked loop and the second phase locked loop that is not enabled when the multiplexer selection logic receives the clock change request.

In yet another example embodiment, when both of the first phase locked loop and the second phase locked loop are enabled, the multiplexer selection logic is configured to output the selection signal to the multiplexer after a current frame data transmission is completed.

In yet another example embodiment, the multiplexer selection logic is configured to output the selection signal to the multiplexer at a time of a next frame, and disable a phase locked loop which is not selected by the multiplexer among the first and second phase locked loops.

In yet another example embodiment, the time is determined to be in one of a vertical sync active period, a vertical back porch, and a vertical front porch, and the multiplexer is configured to select and output a clock signal that does not interfere with a communication frequency of the transmitting apparatus.

In one or more example embodiments, a device includes a first component configured to generate a reference clock signal, and a second component configured to receive the reference clock signal, generate a first clock signal and a second clock signal in response to the reference clock signal, the first clock signal and the second clock signals having different frequencies, select one of the first clock signal and the second clock signal as a main clock signal according to a selection signal, and convert parallel data into serial data for transmission to a receiver, in response to the main clock signal.

In yet another example embodiment, the second component is further configured to receive the selection signal from a signal generator in response to a clock change request.

In yet another example embodiment, the second component includes a first phase locked loop and a second phase locked loop, the signal generator is configured to transmit at least one of a first enable signal to enable the first phase locked loop to generate the first clock signal, if the first phase locked loop is not enabled at the time of receiving the clock change request by the signal generator, and a second enable signal to enable the second phase locked loop to generate the second clock signal, if the second phase locked loop is not enabled at the time of receiving the clock change request by the signal generator. If both of the first phase locked loop and the second phase locked loop are enabled, the signal generator is configured to output the selection signal to the multiplexer at a time after a current frame data transmission is completed, the time corresponding to a subsequent frame and being in one of a vertical sync active period, a vertical back porch, and a vertical front porch and disable one of the first phase locked loop and the second phase locked loop for which the signal generator does not transmit the corresponding one of the first enable signal and the second enable signal.

In yet another example embodiment, the selection signal generator is in the second component, is in the first component, or is between the first component and the second component.

### BRIEF DESCRIPTION OF THE DRAWINGS

The above and other features and advantages of the inventive concept will become more apparent by describing in detail exemplary embodiments thereof with reference to the attached drawings in which:

FIG. 1 is a schematic block diagram of a data interface system, according to one or more example embodiments;

FIG. 2 is a block diagram of the data transmission apparatus of FIG. 1, according to one or more example embodiments;

FIG. 3A is a detailed block diagram of the data transmission apparatus of FIG. 2, according to one or more example embodiments;

FIG. 3B is a detailed block diagram of the data transmission apparatus of FIG. 2, according to one or more example embodiments;

FIG. 3C is a detailed block diagram of the data transmission apparatus of FIG. 2, according to one or more example embodiments;

FIG. 3D is a detailed block diagram of the data transmission apparatus of FIG. 2, according to one or more example embodiments;

FIG. 4 is a flowchart of a method of changing a clock signal, according to one or more example embodiments;

FIG. 5A is a timing chart showing the relationship between the clock signal CLK and the data SDATA, according to one or more example embodiments;

FIG. 5B is a timing chart showing the relationship between the clock signal CLK and the data SDATA, according to one or more example embodiments;

FIG. 6A is a timing chart showing the relationship between the clock signal CLK and the data SDATA, according to an example embodiment;

FIG. 6B is a timing chart showing the relationship between the clock signal CLK and the data SDATA, according to one or more example embodiments; and

FIG. 7 is a block diagram of an electronic system, according to one or more example embodiments.

### DETAILED DESCRIPTION OF EXAMPLE EMBODIMENTS

Inventive concepts will now be described more fully hereinafter with reference to the accompanying drawings, in which example embodiments of inventive concepts are shown. Inventive concepts may, however, be embodied in many different forms and should not be construed as limited to example embodiments set forth herein. Rather, example embodiments are provided so that this disclosure will be thorough and complete, and will fully convey the scope of inventive concepts to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing example embodiments only and is not intended to be limiting of inventive concepts. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

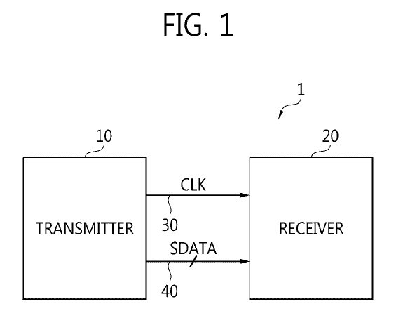

FIG. 1 is a schematic block diagram of a data interface system, according to one or more example embodiments. In FIG. 1, a data interface system 1 includes a data transmission apparatus 10, a data receiver 20, a clock lane 30, and at least one data lane 40. It is assumed that the data interface system 1 is a mobile industry processor interface (MIPI) system using MIPI. Although only one data lane 40 is illustrated in FIG. 1, inventive concepts are not limited thereto. Furthermore, MIPI is presented as an example of an interface for purposes of describing example embodiments. However, inventive concepts are not limited thereto and may include any other known or to be developed interfaces usable in a display system.

MIPI is one of serial interface standards for connecting a processor with peripheral devices. MIPI is a standard defined by the MIPI alliance. MIPI D-PHY is a high-speed digital serial interface. MIPI D-PHY display serial interface (DSI) and camera serial interface (CSI) are protocol standard specifications.

The data transmission apparatus 10 may transmit data to the data receiver 20 according to a MIPI standard (e.g., a MIPI alliance specification for D-PHY). The data transmission apparatus 10 may be referred to as a master device. The data receiver 20 may receive data from the data transmission apparatus 10 according to the MIPI standard and may be referred to as a slave device.

A clock signal CLK may be a unidirectional signal transmitted from the data transmission apparatus 10 to the data receiver 20 through the clock lane 30. Data SDATA may be a unidirectional or a bi-directional signal. In one or more example embodiments of inventive concepts, it is assumed that the data SDATA is a unidirectional serial signal transmitted from the data transmission apparatus 10 to the data receiver 20.

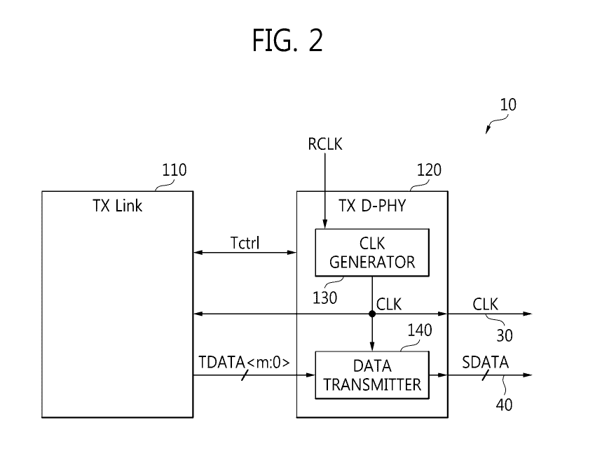

FIG. 2 is a block diagram of the data transmission apparatus of FIG. 1, according to one or more example embodiments. Referring to FIG. 2, the data transmission apparatus 10 includes a transmission link module 110 (first component) and a transmission D-PHY module 120 (second component). While FIG. 2 and example embodiments described in relation thereto, refer to individual and separate components of the data transmission apparatus 10, each of which implements one or more functions, the data transmitter 10 may include a processor and a memory. The memory may have computer-readable instructions stored thereon, which when executed by the processor, transform the processor into a special purpose processor for carrying out the functionalities of the data transmission apparatus 10, as described below according to one or more example embodiment.

In one or more example embodiments, the transmission link module 110 controls the operations of the transmission D-PHY module 120 using a transmission control signal Tctrl. The transmission link module 110 may receive the clock signal CLK from the transmission D-PHY module 120 and may synchronize the transmission control signal Tctrl with the clock signal CLK. The transmission link module 110 may output (m+1)-bit parallel transmission data TDATA<m:0> to the transmission D-PHY module 120 for data transmission, where “m” is an integer equal to or greater than 1.

The transmission D-PHY module 120 may include a data transmitter 140 and a clock generator 130. In one or more example embodiments, the clock generator 130 receives a reference clock signal RCLK and generates the clock signal CLK, which may be transmitted to the clock lane 30 and to the data transmitter 140. The clock generator 130 may also send the clock signal CLK to the transmission link module 110.

The data transmitter 140 may convert the transmission data TDATA<m:0> from parallel data into the serial data SDATA. The data transmitter 140 may convert parallel data received by “k” bits into serial data, where “k” is an integer greater than or equal to 2. For instance, when “k” is 6, the data transmitter 140 may convert first 6-bit parallel data TDATA<5:0> in the transmission data TDATA<m:0> into first serial data SDATA and output the first serial data SDATA to the data lane 40.

Although not shown in FIG. 2, the transmission D-PHY module 120 may also include a bias circuit and a voltage regulator to generate voltage and/or current necessary for the operation of the transmission D-PHY module 120 and may also include a phase locked loop (PLL) circuit to generate a clock signal.

The clock lane 30 may transmit the clock signal CLK to a receiving terminal (e.g., the slave device described above) and the data lane 40 may transmit the serial data SDATA to the receiving terminal.

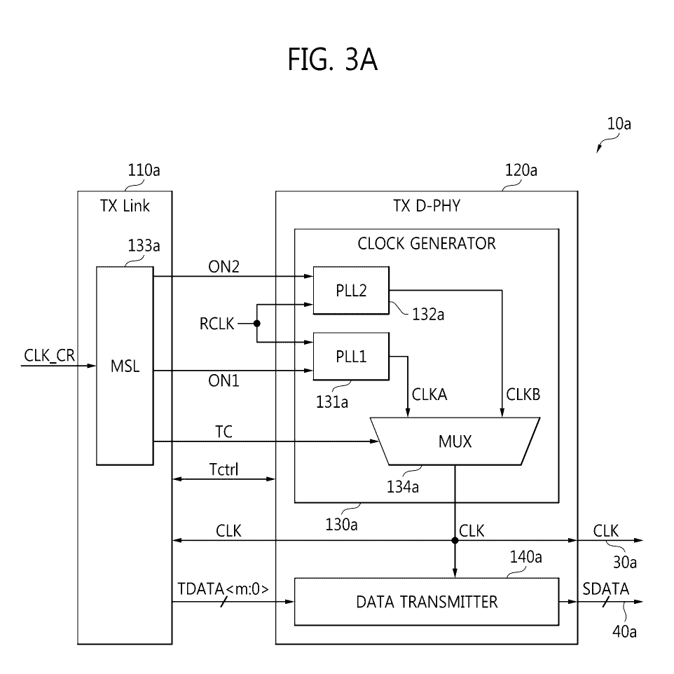

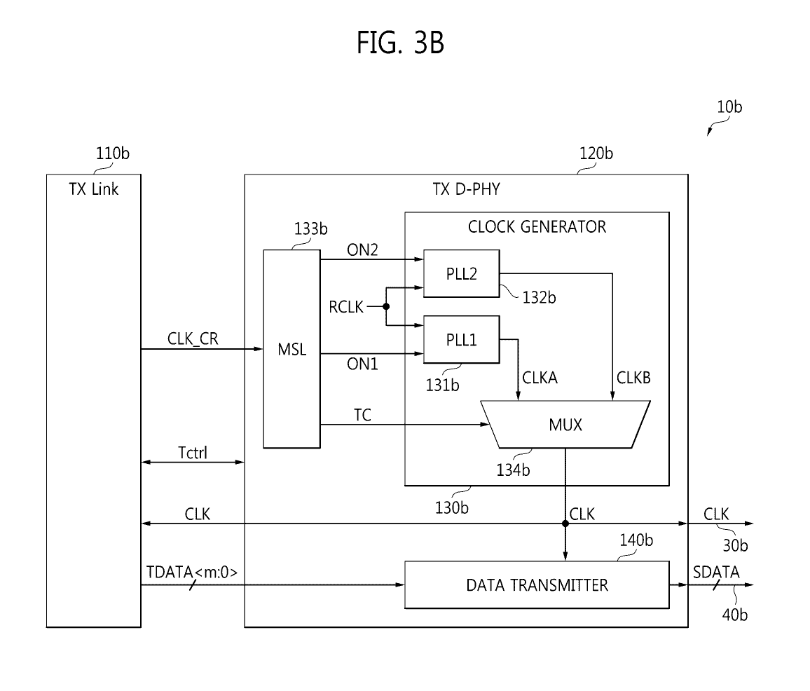

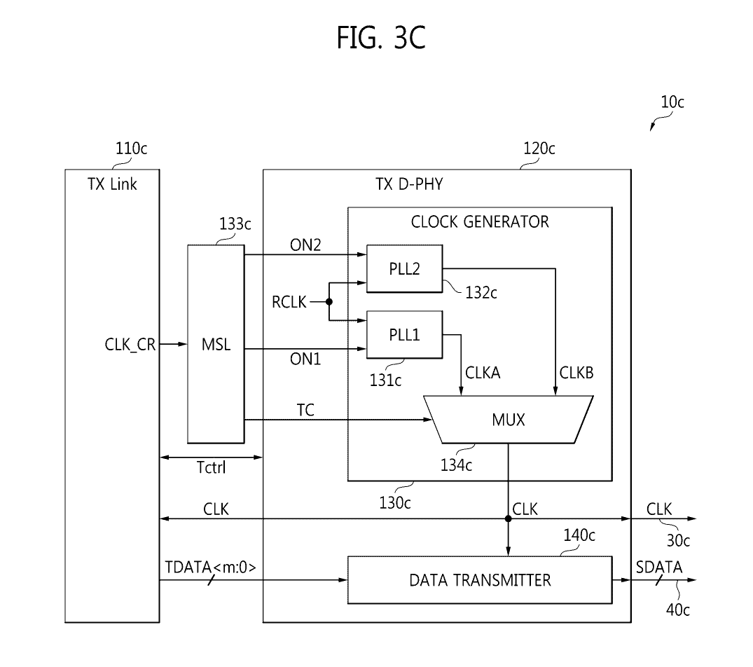

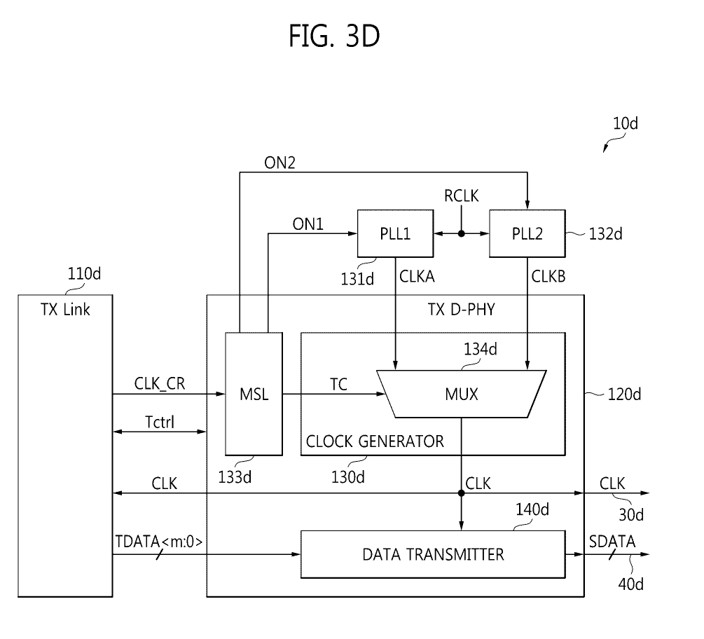

FIG. 3A is a detailed blocked diagram of the data transmission apparatus of FIG. 2, according to one or more example embodiments. FIG. 3B is a detailed blocked diagram of the data transmission apparatus of FIG. 2, according to one or more example embodiments. FIG. 3C is a detailed blocked diagram of the data transmission apparatus of FIG. 2, according to one or more example embodiments. FIG. 3D is a detailed blocked diagram of the data transmission apparatus of FIG. 2, according to one or more example embodiments. Although the data transmission apparatuses 10a through 10d include two PLLs in one or more example embodiments illustrated in FIGS. 3A through 3D, inventive concepts are not limited thereto. For example, the data transmission apparatus 10 may include at least three PLLs.

Referring to FIG. 3A, a transmission link module 110a may include a multiplexer selection logic (MSL) 133a (the MSL may also be referred to as a signal generator). A transmission D-PHY module 120a may include a clock generator 130a. The clock generator 130a may include a first PLL 131a, a second PLL 132a, and a multiplexer (MUX) 134a.

In one or more example embodiments, the MSL 133a receives a clock change request CLK_CR from a host (not shown), and outputs a first enable signal ON1 to the first PLL 131a and a second enable signal ON2 to the second PLL 132a in response to the clock change request CLK_CR. The MSL 133a may also output a selection signal TC to the MUX 134a.

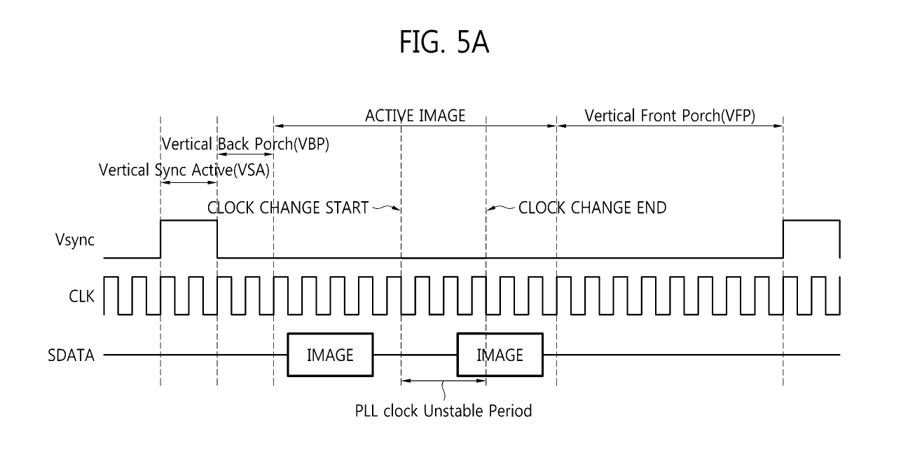

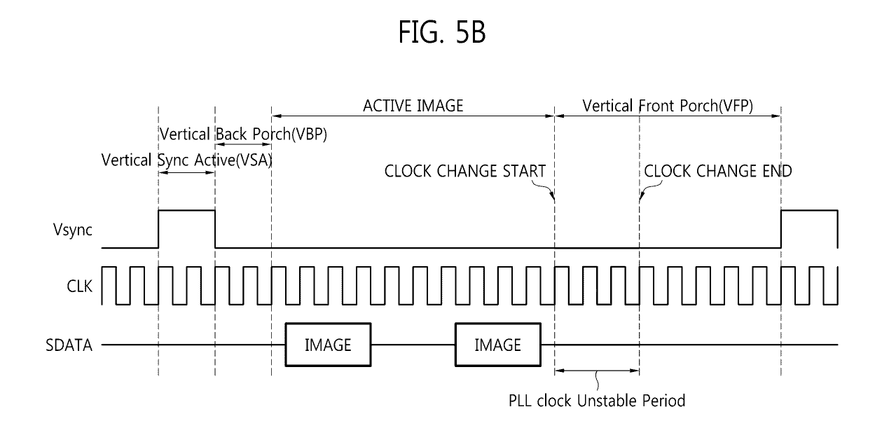

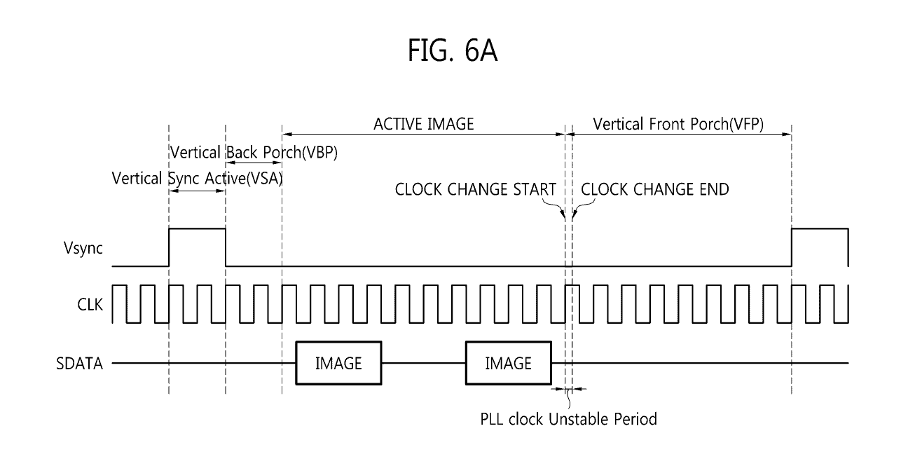

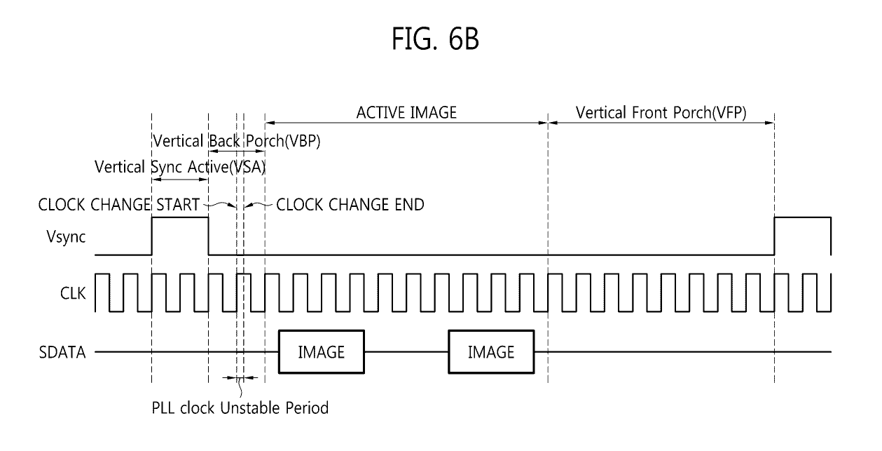

In one or more example embodiments, the MSL 133a may output the selection signal TC to the MUX 134a at any other time than during frame data transmission time based on various synchronous signals (e.g., a vertical synchronization signal, a vertical back porch signal, and a vertical front porch signal). The MSL 133a may output the first enable signal ON1 and/or the second enable signal ON2 at a desired (and/or alternatively, predetermined) time before the selection signal TC is output. The desired (and/or alternatively, predetermined) time may be a time taken for a PLL to be enabled and stabilized. The details about the operation timing of the MSL 133a will be described with reference to FIGS. 5 and 6 below.

Although the reference clock signal RCLK, the selection signal TC, the first enable signal ON1, and the second enable signal ON2 are separated from the transmission control signal Tctrl, in one or more example embodiments illustrated in FIG. 3A the transmission control signal Tctrl may include the reference clock signal RCLK, the selection signal TC, the first enable signal ON1, and the second enable signal ON2.

The first PLL 131a may be enabled in response to the first enable signal ON1. The second PLL 132a may be enabled in response to the second enable signal ON2. When the first PLL 131a is enabled, the first PLL 131a may generate a first clock signal CLKA based on the reference clock signal RCLK. When the second PLL 132a is enabled, the second PLL 132a may generate a second clock signal CLKB based on the reference clock signal RCLK. In one or more example embodiments, it may take a certain amount of time for the first or second PLL 131a or 132a to stably output the clock signal CLKA or CLKB.

The second clock signal CLKB may have a frequency which does not interfere with a communication frequency of a device in which the transmission link module 110a is installed (e.g., a display device) in order to avoid electromagnetic interference (EMI) which occurs when the communication frequency and the frequency of the first clock signal CLKA interfere with each other. However, inventive concepts are not limited thereto. Similarly, the first clock signal CLKA may have a frequency which does not interfere with the communication frequency.

The first PLL 131a may output the first clock signal CLKA to the MUX 134a and the second PLL 132a may output the second clock signal CLKB to the MUX 134a. The MUX 134a may select and output either the first clock signal CLKA or the second clock signal CLKB in response to the selection signal TC. In one or more example embodiments, it may take a certain amount of time for the MUX 134a to stably output the selected clock signal CLK. The amount of time taken by the MUX 134a to stably output the clock signal CLK may be shorter than the amount of time taken by the PLL 131a or 132a to stably output the clock signal CLKA or CLKB, which will be further described below.

The MUX 134a may transmit the clock signal CLK through a clock lane 30a and may transmit it to a data transmitter 140a. The MUX 134a may also output the clock signal CLK to the transmission link module 110a. Although the clock signal CLK is output to the transmission link module 110a as it is in one or more example embodiments illustrated in FIG. 3A, the clock signal CLK may be converted to a different clock signal, e.g., a link module clock signal before being output to the transmission link module 110a.

In one or more example embodiments, the transmission link module 110a controls the operation of a transmission D-PHY module 120a using the transmission control signal Tctrl. The transmission link module 110a may receive the clock signal CLK from the transmission D-PHY module 120a and may synchronize the transmission control signal Tctrl and the transmission data TDATA with the clock signal CLK. The transmission link module 110a may output the transmission control signal Tctrl and the transmission data TDATA which have been synchronized with the clock signal CLK to the transmission D-PHY module 120a.

The data transmitter 140a may convert the transmission data TDATA<m:0> from parallel data to the serial data SDATA and may output the serial data SDATA synchronized with the clock signal CLK to a data lane 40a. The clock lane 30a may transfer the clock signal CLK to a receiving terminal and the data lane 40a may transfer the serial data SDATA to the receiving terminal.

The data transmission apparatus 10b illustrated in FIG. 3B is different from the data transmission apparatus 10a illustrated in FIG. 3A in terms of the positions of elements. In the descriptions of FIGS. 3B and 3C, the differences from FIG. 3A will be focused on.

Referring to FIG. 3B, a transmission D-PHY module 120b may include an MSL 133b and a clock generator 130b may include a first PLL 131b, a second PLL 132b, and a MUX 134b. The MSL 133b may receive the clock change request CLK_CR from the host (not shown) through a transmission link module 110b. The MSL 133a may output the first enable signal ON1 to the first PLL 131b and the second enable signal ON2 to the second PLL 132b in response to the clock change request CLK_CR. The MSL 133b may also output the selection signal TC to the MUX 134b.

Although the reference clock signal RCLK and the clock change request CLK_CR are separated from the transmission control signal Tctrl in the one or more example embodiments illustrated in FIG. 3B, the transmission control signal Tctrl may include the reference clock signal RCLK and the clock change request CLK_CR.

The data transmission apparatus 10c illustrated in FIG. 3C is different from the data transmission apparatus 10a illustrated in FIG. 3A in terms of the positions of elements. Referring to FIG. 3C, an MSL 133c may be placed outside a transmission link module 110c and outside a transmission D-PHY module 120c (e.g., in between the transmission link module 110c and the transmission D-PHY module 120c). A clock generator 130c may include a first PLL 131c, a second PLL 132c, and a MUX 134c. The MSL 133c may receive the clock change request CLK_CR from the host through the transmission link module 110c. Although the reference clock signal RCLK is separated from the transmission control signal Tctrl in the one or more example embodiments illustrated in FIG. 3C, the transmission control signal Tctrl may include the reference clock signal RCLK.

The data transmission apparatus 10d illustrated in FIG. 3D is different from the data transmission apparatus 10a illustrated in FIG. 3A in terms of the positions of elements. Referring to FIG. 3D, a transmission D-PHY module 120d may include an MSL 133d, a first PLL 131d and a second PLL 132d may be placed outside a transmission link module 110d and outside the transmission D-PHY module 120d. A clock generator 130d may include a MUX 134d. The MSL 133d may receive the clock change request CLK CR from the host through the transmission link module 110d. Although the clock change request CLK_CR is separated from the transmission control signal Tctrl in the one or more example embodiments illustrated in FIG. 3D, the transmission control signal Tctrl may include the clock change request CLK_CR.

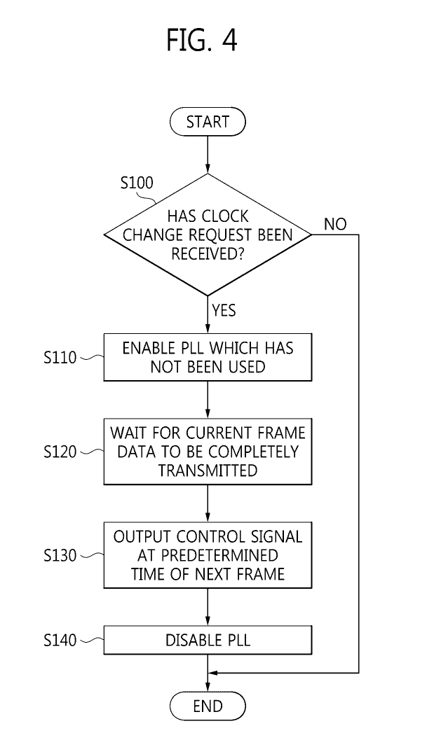

FIG. 4 is a flowchart of a method of changing a clock signal, according to one or more example embodiments. The operation of the MSL 133 that changes a clock signal will be described below with reference to FIG. 4. As for the terminology, a per-frame operation includes an operation of securing transmission of current frame data when there is a clock change request and changing a clock signal in a following frame transmission period while the current frame data is not being transmitted.

In operation S100, the MSL 133 determines whether the clock change request CLK_CR, which is output by a host, is received by the MSL 133. For instance, the clock change request CLK_CR may be output from the host in order to avoid EMI when a clock frequency and a communication frequency interfere with each other in the data interface system 1 as described above, or may be output from the host in order to return to an original clock signal when an EMI filter frequency is no longer needed due to the communication not being necessary any more. However, inventive concepts are not to the above described conditions under which the clock change request CLK_CR is generated and include generation of the clock change request CLK_CR under various conditions.

If in operation S100, the MSL 133 determines that clock change request CLK-CR is not received, the process ends. However, if the MSL 133 determines that the clock change request CLK-CR is received, then in operation S110, the MSL 133 enables the second PLL 132 if the first PLL 131 is operating or enables the first PLL 131 if the second PLL 132 is operating. Thereafter, in operation S120, the MSL 133 waits for current frame data to be completely transmitted. Here, the MSL 133 waits in order to prevent data loss from occurring due to the change in the clock signal during the transmission of the frame data, thereby realizing the per-frame operation.

Thereafter in operation S130, the MSL 133 outputs the selection signal TC at a desired (and/or alternatively, predetermined) time of the next frame. The MSL 133 may set an output time of the selection signal TC to any time other than a frame data transmission time based on various synchronous signals (e.g., a vertical synchronization signal, a vertical back porch signal, and a vertical front porch signal). The desired (and/or alternatively, predetermined) time may be changed, which will be described in detail later.

After outputting the selection signal TC, in operation S140, the MSL 133 terminates (disables) the operation of the PLL 131 or 132 which was used. In at least one example embodiment, the PLL 131 or 132 which is not used is disabled to prevent unnecessary power consumption.

FIG. 5A is a timing chart showing the relationship between the clock signal CLK and the data SDATA, according to one or more example embodiments. FIG. 5B is a timing chart showing the relationship between the clock signal CLK and the data SDATA, according to one or more example embodiments. MIPI DSI is used in example embodiments described below, but inventive concepts are not limited thereto.

FIG. 5A is a timing chart showing the relationship between the clock signal CLK and the data SDATA in case where a multi-PLL is not used and the clock signal CLK is changed without a clock change time being set. Referring to FIG. 5A, a vertical synchronization signal Vsync indicates the start of a frame. The vertical synchronization signal Vsync is activated during a vertical sync active (VSA) period. A vertical back porch (VBP) is a wait time before transmission of image data from the data transmission apparatus 10 to the data receiver 20 after the vertical synchronization signal Vsync, that is, a period between the deactivation of the vertical synchronization signal Vsync and the start of the transmission of the image data. A vertical front porch (VFP) is a wait time after the end of the transmission of the image data, i.e., a period between the end of the transmission of the image data and the next activation of the vertical synchronization signal Vsync. In other words and in one or more example embodiments, VFP and/or VBP is a period during which no image data is being input.

As shown in FIG. 5A, a PLL clock signal is unstable when the clock signal CLK is changed during image transmission, i.e., an active image period. When the clock signal CLK is unstable, the data SDATA synchronized with the clock signal CLK also becomes unstable. As a result, data transmission may fail. In addition, when the clock signal CLK is changed using a single PLL as shown in FIG. 5A, a PLL clock unstable period may correspond to a time taken for the PLL to be stabilized. The time taken for PLL stabilization may be a time corresponding to several periods of the clock signal CLK, as shown in FIG. 5A.

FIG. 5B is a timing chart showing the relationship between the clock signal CLK and the data SDATA in case where a multi-PLL is not used and the clock signal CLK is changed with a clock change time being set. The descriptions will be focused on the differences from the timing chart shown in FIG. 5A.

As shown in FIG. 5B, when the start of the clock change time is set to the end of the transmission of the image data SDATA, i.e., the start of the VFP, the clock signal CLK may be changed after the end of the image transmission, i.e., the end of the active image period. In this case, the PLL clock unstable period caused by the clock change does not overlap the data transmission period, and therefore, the data transmission may be stable. However, when a single PLL instead of a multi-PLL is used, the PLL clock unstable period is longer than when the multi-PLL is used, which degrades the stability of data transmission. In addition, when a conventional method of avoiding EMI using clock change is used without using a multi-PLL, clock change at runtime is not considered. Accordingly, special software, implemented and executed by a processor, is necessary to control the end of data transmission and the star of clock change.

FIG. 6A is a timing chart showing the relationship between the clock signal CLK and the data SDATA, according to one or more example embodiments. FIG. 6A is a timing chart showing the relationship between the clock signal CLK and the data SDATA when the clock signal CLK is changed in the VFP.

Referring to FIG. 6A, the timing chart shows the state of a frame after the MSL 133 enables the second PLL 132 by outputting the second enable signal ON2 to the second PLL 132 in response to the clock change request CLK CR at a previous frame. In other words, the second PLL 132 has been enabled by the second enable signal ON2 output from the MSL 133 at the previous frame and is thus outputting the second clock signal CLKB.

The MSL 133 may receive various synchronization signals (e.g., a VBP signal, a VFP signal, and a VSA signal) and determine a data transmission time. Accordingly, as shown in FIG. 6A, the MSL 133 may output the selection signal TC to the MUX 134 at the end of the active image period, that is, the start of the VFP. The MUX 134 may change the clock signal CLK, for example, from the first clock signal CLKA to the second clock signal CLKB, according to the selection signal TC.

In this case, the PLL clock unstable period may correspond to a period while the clock signal CLK is changed by the MUX 134, i.e., a switching time. Time taken for PLL stabilization may be shorter than the period of the clock signal CLK, as shown in FIGS. 6A and 6B, so that data transmission stability is increased as compared to a case where a single PLL is used.

FIG. 6B is a timing chart showing the relationship between the clock signal CLK and the data SDATA, according to one or more example embodiments. FIG. 6B is a timing chart showing the relationship between the clock signal CLK and the data SDATA when the clock signal CLK is changed in the VBP. The timing chart illustrated in FIG. 6B is different from that illustrated in FIG. 6A in that clock change occurs in the VBP instead of the VFP.

Referring to FIG. 6B, the timing chart shows the state of a frame after the MSL 133 enables the second PLL 132 by outputting the second enable signal ON2 to the second PLL 132 in response to the clock change request CLK CR at a previous frame. In other words, the second PLL 132 has been enabled by the second enable signal ON2 output from the MSL 133 at the previous frame and is thus outputting the second clock signal CLKB.

The MSL 133 may receive various synchronization signals (e.g., a VBP signal, a VFP signal, and a VSA signal) and determine a data transmission time. Accordingly, as shown in FIG. 6B, the MSL 133 may output the selection signal TC to the MUX 134 before the active image period, that is, at any time during the VBP. The MUX 134 may change the clock signal CLK, for example, from the first clock signal CLKA to the second clock signal CLKB, according to the selection signal TC.

In this case, the PLL clock unstable period may correspond to a period while the clock signal CLK is changed by the MUX 134, i.e., a switching time. Time taken for PLL stabilization may be shorter than the period of the clock signal CLK, as shown in FIGS. 6A and 6B, so that data transmission stability is increased as compared to a case where a single PLL is used.

Inventive concepts are not restricted to the above-described example embodiments and accordingly, clock change may occur at any other time than during data transmission.

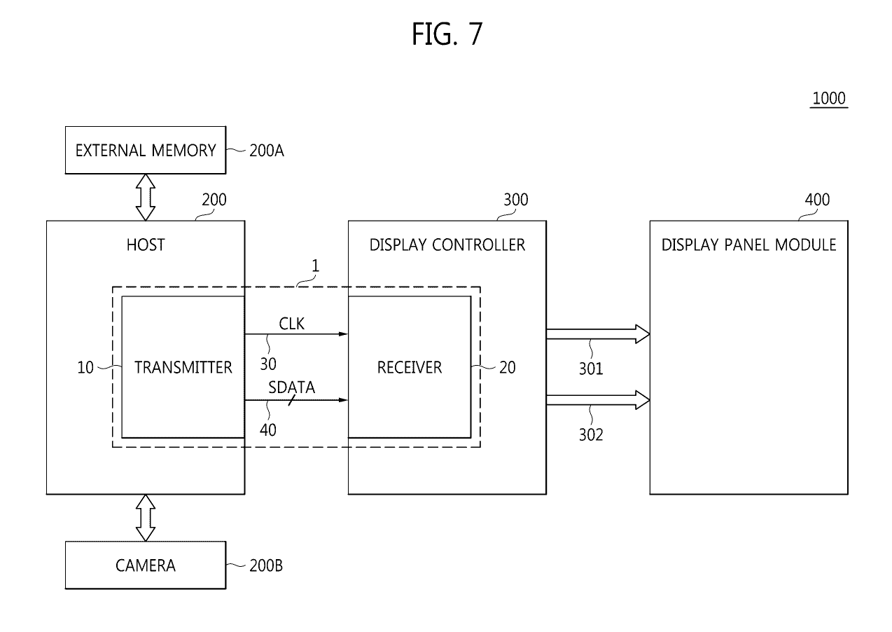

FIG. 7 is a block diagram of an electronic system, according to one or more example embodiments. Referring to FIG. 7, the electronic system 1000 includes a host 200, an external memory 200A, a camera 200B, a display controller 300, and a display panel module 400. The electronic system 1000 may process image data and may display the processed image data on the display panel module 400.

The electronic system 1000 may be implemented as a personal computer (PC), a data server, or a portable electronic device. The portable electronic device may be a laptop computer, a cellular phone, a smart phone, a tablet PC, a personal digital assistant (PDA), an enterprise digital assistant (EDA), a digital still camera, a digital video camera, a portable multimedia player (PMP), a personal navigation device or portable navigation device (PND), a handheld game console, or an e-book.

The electronic system 1000 may be a mobile device which supports MIPI. The electronic system 1000 may be implemented as a smart phone, a tablet PC, a digital camera, a camcorder, a PDA, a PMP, a mobile internet device (MID), or a wearable computer.

The host 200 and the display controller 300 are connected with each other through a first interface, e.g., the MIPI data interface system 1. The display controller 300 and the display panel module 400 are connected with each other through a second interface, e.g., display interfaces 301 and 302. In one or more example embodiments of inventive concepts, a MIPI interface or a MIPI protocol is exemplified for convenience′ sake in the description provided herein, but inventive concepts may also be applied to display system including interfaces than the MIPI interface and a timing controller.

The data interface system 1 includes one clock lane 30 and at least one data lane 40. The data lane 40 may be bi-directional or unidirectional.

The host 200 may control the external memory 200A, the camera 200B, and/or the display controller 300. The host 200 may be implemented as an integrated circuit, a system on chip (SoC), an application processor (AP), or a mobile AP.

As described above, according to one or more example embodiments of inventive concepts, a clock signal is changed at runtime in case where EMI may occur, so that EMI is avoided. In addition, at least two PLLs (i.e., a multi-PLL) which generate different clock signals are used to change the clock signal, so that an unstable period of a clock is reduced when the clock is changed. An unused PLL among the PLLs is disabled, so that power consumption is reduced. Moreover, when an EMI filter frequency is used in a data interface system, a per-frame operation is performed, so that transmission of current frame data is secured and a clock signal is changed at other time than a data transmission period. As a result, data/command transmission stability is increased.

While inventive concepts have been particularly shown and described with reference to one or more example embodiments thereof, it will be understood by those of ordinary skill in the art that various changes in forms and details may be made therein without departing from the spirit and scope of inventive concepts as defined by the following claims.

What is claimed is:

1. A data transmission apparatus comprising:
a transmission link module configured to generate a reference clock signal; and
a transmission D-PHY module, the transmission D-PHY module including,
a first phase locked loop configured to,
receive the reference clock signal, and
generate a first clock signal,
a second phase locked loop configured to,
receive the reference clock signal, and
generate a second clock signal having a different frequency than the first clock signal,
a multiplexer configured to select and output one of the first and second clock signals as a clock signal according to a selection signal, and
a data transmitter configured to convert parallel data into serial data in response to the clock signal for transmission to a receiver.

2. The data transmission apparatus of claim 1, wherein the transmission link module comprises:
a multiplexer selection logic configured to output the selection signal to the multiplexer in response to a clock change request.

3. The data transmission apparatus of claim 2, wherein the first phase locked loop is enabled in response to a first enable signal and the second phase locked loop is enabled in response to a second enable signal, the first enable signal and the second enable signal being generated by the transmission link module.

4. The data transmission apparatus of claim 3, wherein the multiplexer selection logic is configured to enable one of the first phase locked loop and the second phase locked loop, that is not enabled when the multiplexer selection logic receives the clock change request.

5. The data transmission apparatus of claim 4, wherein if both of the first phase locked loop and the second phase locked loop are enabled, the multiplexer selection logic is configured to output the selection signal to the multiplexer after a current frame data transmission is completed.

6. The data transmission apparatus of claim 5, wherein the multiplexer selection logic is configured to,
change and output the selection signal to the multiplexer at a time of a next frame, and
disable a phase locked loop which is not selected by the multiplexer among the first and second phase locked loops.

7. The data transmission apparatus of claim 6, wherein
the time is determined to be in one of a vertical sync active period, a vertical back porch, and a vertical front porch,
and the multiplexer is configured to select and output a clock signal that does not interfere with a communication frequency of the data transmission apparatus.

8. The data transmission apparatus of claim 1, wherein the transmission D-PHY module further comprises:
a multiplexer selection logic configured to output the selection signal to the multiplexer in response to a clock change request.

9. The data transmission apparatus of claim 1, further comprising:
a multiplexer selection logic located between the transmission link module and the transmission D-PHY module, the multiplexer selection logic configured to output the selection signal to the multiplexer in response to a clock change request.

10. A data interface system comprising:
a receiver;
a data communication link;
a clock communication link; and
a transmission apparatus, the transmission apparatus including a transmission link module and a transmission D-PHY module, the transmission D-PHY module including,
a first phase locked loop configured to,
receive a reference clock signal, and
generate a first clock signal,
a second phase locked loop configured to,
receive the reference clock signal, and
generate a second clock signal having a different frequency than the first clock signal,
a multiplexer configured to select and output either of the first and second clock signals as a clock signal according to a selection signal, and
a data transmitter configured to convert parallel data into serial data in response to the clock signal for transmission to the receiver.

11. The data interface system of claim 10, wherein the transmission link module comprises:
a multiplexer selection logic configured to output the selection signal to the multiplexer in response to a clock change request.

12. The data interface system of claim 11, wherein the first phase locked loop is enabled in response to a first enable signal and the second phase locked loop is enabled in response to a second enable signal.

13. The data interface system of claim 12, wherein the multiplexer selection logic is configured to enable one of the first phase locked loop and the second phase locked loop, that is not enabled when the multiplexer selection logic receives the clock change request.

14. The data interface system of claim 13, wherein when both of the first phase locked loop and the second phase locked loop are enabled, the multiplexer selection logic is configured to output the selection signal to the multiplexer after a current frame data transmission is completed.

15. The data interface system of claim 14, wherein the multiplexer selection logic is configured to,
output the selection signal to the multiplexer at a time of a next frame, and
disable a phase locked loop which is not selected by the multiplexer among the first and second phase locked loops.

16. The data interface system of claim 15, wherein
the time is determined to be in one of a vertical sync active period, a vertical back porch, and a vertical front porch, and
the multiplexer is configured to select and output a clock signal that does not interfere with a communication frequency of the transmitting apparatus.

17. A device comprising:
a first component configured to generate a reference clock signal; and
a second component configured to,
receive the reference clock signal,
generate a first clock signal and a second clock signal in response to the reference clock signal, the first clock signal and the second clock signals having different frequencies,
select one of the first clock signal and the second clock signal as a main clock signal according to a selection signal, and
convert parallel data into serial data for transmission to a receiver, in response to the main clock signal.

18. The device of claim 17, wherein the second component is further configured to receive the selection signal from a signal generator in response to a clock change request.

19. The device of claim 18, wherein
the second component includes a first phase locked loop and a second phase locked loop, and
the signal generator is configured to transmit at least one of,
a first enable signal to enable the first phase locked loop to generate the first clock signal, if the first phase locked loop is not enabled at the time of receiving the clock change request by the signal generator, and
a second enable signal to enable the second phase locked loop to generate the second clock signal, if the second phase locked loop is not enabled at the time of receiving the clock change request by the signal generator, wherein
if both of the first phase locked loop and the second phase locked loop are enabled, the signal generator is configured to,
output the selection signal to the multiplexer at a time after a current frame data transmission is completed, the time corresponding to a subsequent frame and being in one of a vertical sync active period, a vertical back porch, and a vertical front porch, and
disable one of the first phase locked loop and the second phase locked loop for which the signal generator does not transmit the corresponding one of the first enable signal and the second enable signal.

20. The device of claim 18, wherein the selection signal generator,
is in the second component,
is in the first component, or
is between the first component and the second component.
